(19) United States
(12) Patent Application Publication
(10) Pub. No.: US 2021/0048787 A1
(43) Pub. Date: Feb. 18, 2021

(54) INTERACTIVE FRAMEWORK FOR AUTOMATIC GENERATION, ANALYSIS AND EXPLORATION OF COMPOSABLE SYSTEM OF SYSTEMS BASED ON A KNOWLEDGE GRAPH

(71) Applicant: Siemens Corporation, Iselin, NJ (US)

(72) Inventors: Lucia Mirabella, Plainsboro, NJ (US); Sanjeev Srivastava, Princeton Junction, NJ (US); Arquimedes Martinez Canedo, Plainsboro, NJ (US); Edward Slavin, III, Robbinsville, NJ (US); Pranav Srinivas Kumar, Plainsboro, NJ (US); Thomas Gruenewald, Somerset, NJ (US); Scott Kolb, Hopewell, NJ (US); Livio Dalloro, Plainsboro, NJ (US); Mike Nicolai, Bierbeek (BE)

(21) Appl. No.: 16/966,959

(22) PCT Filed: Aug. 29, 2018
(86) PCT No.: PCT/US2018/048419

§ 371 Date: Aug. 3, 2020

Related U.S. Application Data
(60) Provisional application No. 62/630,340, filed on Feb. 14, 2018.

(51) Int. Cl. G05B 19/042

(52) U.S. Cl. CPC G05B 19/042; G05B 2219/2642

(57) ABSTRACT

Systems (500) and methods (400) for an interactive system for automatic generation, analysis and exploration of composable system of systems based on knowledge graphs. A method (400) includes receiving (405) a scenario (110) and a domain ontology (111); determining (410) structures (132), attributes (133), and capabilities (131) from the domain ontology; generating (415) design alternatives (146) based on the scenario using the structures, attributes, and capabilities; performing (430) an evaluation (159) of the design alternatives based on the scenario; generating (445) an SoS design (300) based on the evaluation; and displaying the SoS design to a user.

### CROSS-REFERENCE TO OTHER APPLICATION

This application claims the benefit of the filing date of U.S. Provisional Patent Applications 62/630,340, filed Feb. 14, 2018 and is hereby incorporated by reference.

### STATEMENT OF GOVERNMENT LICENSE RIGHTS

This invention was made with government support under HR0011-16-C0097 awarded by Defense Advanced Research Projects Agency (DARPA). The government has certain rights in the invention.

### TECHNICAL FIELD

The present disclosure is directed, in general, systems and methods for operation and control of an automation system, including in particular an interactive framework for automatic generation, analysis and exploration of composable system of systems based on knowledge graphs.

### BACKGROUND OF THE DISCLOSURE

Many real world problems, like task scheduling in a factory, medical planning in battle conditions, resource planning for manufacturing, design of engineering systems can be seen as efforts to optimally design and configure complex systems of systems (SoS), where multiple nested components can be utilized and combined. In many cases, SoS components exhibit behaviors in multiple domains (e.g. electrical, mechanical, thermodynamic domains for engineering systems) and such behaviors depend on the way single elements are composed and connected with each other.

### SUMMARY OF THE DISCLOSURE

Disclosed embodiments include systems and methods for an interactive framework for automatic generation, analysis and exploration of composable system of systems based on knowledge graphs. A method includes receiving a scenario and a domain ontology; determining structures, attributes, and capabilities from the domain ontology; generating design alternatives based on the scenario using the structures, attributes, and capabilities; performing an evaluation of the design alternatives based on the scenario; and generating an SoS design based on the evaluation.

In some embodiments, the method includes identifying a portion of the SoS design and triggering a detailed analysis on the portion of the SoS design. In some embodiments, the method includes identifying potential problems and displaying the potential problems to a user. In some embodiments, the potential problems include bottlenecking of the control system and potential lack of resources. In some embodiments, the method further includes presenting suggestions for altering the SoS design to increase resilience to unplanned events. In some embodiments, the method further includes filtering design alternatives based on requirements of the scenario before the evaluation occurs. In some embodiments, the design alternatives are evaluated based on a key performance indicator provided in the scenario.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1A illustrates an example of a schematic of a system for an interactive framework for automatic generation, analysis and exploration of composable system of systems based on knowledge graphs in accordance with disclosed embodiments;

FIG. 1B illustrates a schematic representation of the process of the system design space exploration for the interactive framework in accordance with disclosed embodiments;

FIG. 1C illustrates a schematic representation of the process of applying a solver of the system to select well-performing designs for the interactive framework in accordance with disclosed embodiments;

FIG. 1D illustrates an example of a trade-off analyzer of the system for the interactive framework in accordance with disclosed embodiments;

FIG. 1E illustrates an example of a discover component of the system for the interactive framework in accordance with disclosed embodiments;

FIG. 1F illustrates an example of a insighter component of the system for the interactive framework in accordance with disclosed embodiments;

FIG. 2 illustrates an example of a type graph including structures, attributes and relationships in accordance with disclosed embodiments;

FIG. 3 illustrates an example of a type graph of an SoS including inheritance, composition, and capabilities in accordance with disclosed embodiments;

FIG. 4 illustrates a process in accordance with disclosed embodiments; and

FIG. 5 illustrates a block diagram of a data processing system in which an embodiment can be implemented.

### DETAILED DESCRIPTION

The Figures discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Design criteria for an SoS often aim at identifying the most performing solution, the most robust configuration or a configuration agile in adapting to evolving environments. However, given the complexity of the SoS and of the solutions space, both the generation of alternative designs as well as the exploration of the trade-offs between different options are challenging tasks. This Specification proposes a framework for automatic generation of SoS design alternatives and for interactive guided exploration of the solution space.

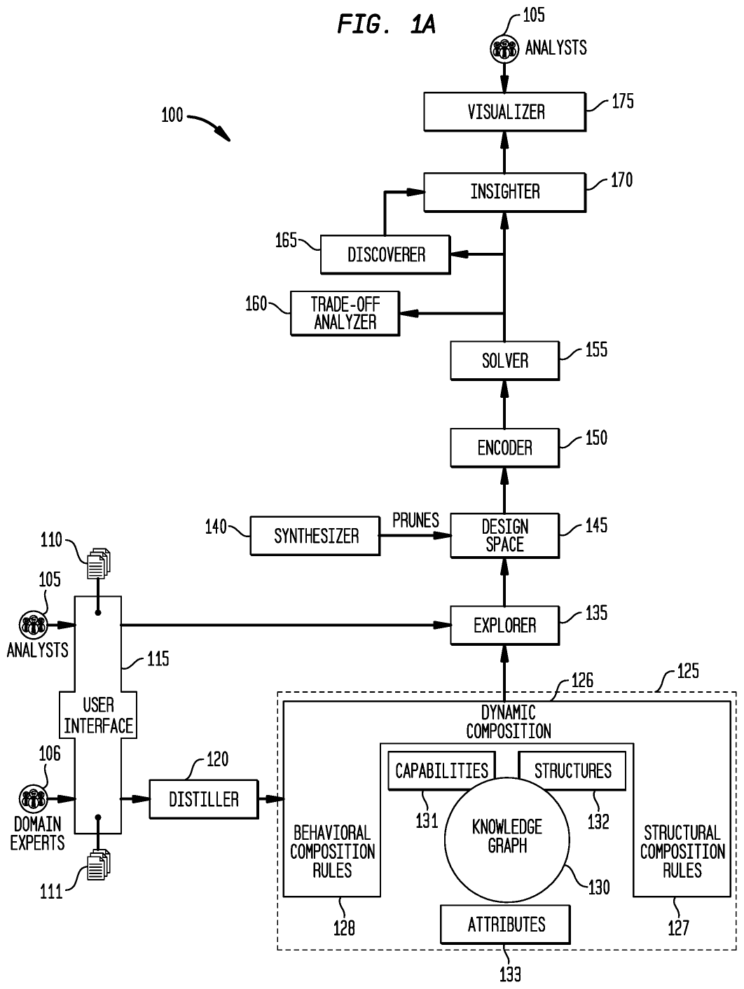

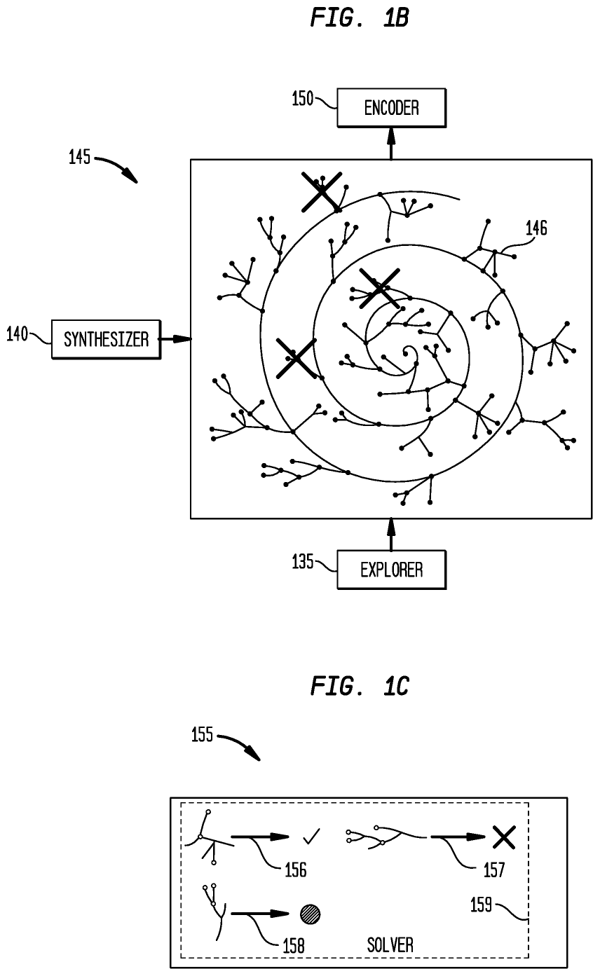

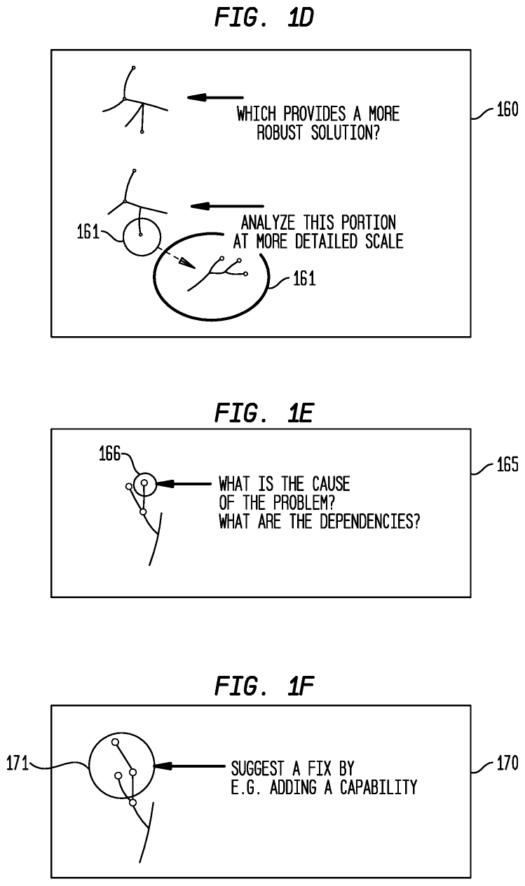

FIG. 1A illustrates an example of a schematic of a system 100 for an interactive framework for automatic generation, analysis and exploration of composable system of systems based on knowledge graphs in accordance with disclosed embodiments. The system 100 receive input from analysts 105 defining a scenario 110 and domain experts 106 encoding domain ontology 111. The system 100 includes a user interface 115; a distiller 120; a SoS modeling paradigm layer 125 including dynamic composition rules 125, behavioral composition rules 126, structural composition rules 127, knowledge graphs 130, capabilities 131, structures 132, and attributes 133; an explorer component 135, a synthesizer 140, a design space 145, an encoder 155, a solver 155, a trade-off analyzer 165, a discoverer component 165, an insighter component 170, and a visualizer 175.

FIG. 1B illustrates an example of a schematic representation of the process of the system design space exploration 145 for the interactive framework in accordance with disclosed embodiments. FIG. 1C illustrates a schematic representation of the process of applying a solver 155 of the system 100 to select well performing designs for the interactive framework in accordance with disclosed embodiments. FIG. 1D illustrates an example of a trade-off analyzer 160 of the system 100 for the interactive framework in accordance with disclosed embodiments. FIG. 1E illustrates an example of a discover component 165 of the system 100 for the interactive framework in accordance with disclosed embodiments. FIG. 1F illustrates an example of an insighter function 170 of the system 100 for the interactive framework in accordance with disclosed embodiments. The embodiments of the system 100 illustrated in FIG. 1A, the design space 145 illustrated in FIG. 1B, the solver 155 illustrated in FIG. 1C, the trade-off analyzer 160 illustrated in FIG. 1D, the discover component 165 illustrated in FIG. 1E, and the insighter function 170 illustrated in FIG. 1F are for illustration only. FIGS. 1A-1F do not limit the scope of this disclosure to any particular implementation of the system 100, the design space 145, the solver 155, the trade-off analyzer, the discover component 165.

FIG. 1A shows the high level block schematic of the proposed system 100. At a high level, the system 100 starts at the bottom left corner of the diagram with the user's input. Two types of users are envisioned, a domain expert 106 that encodes the domain specific elements and rules (the “domain ontology” 111), and an analyst 105 that creates a specific “scenario” 110, defining the instances available in the SoS and the objectives of the analysis. These inputs are collected through a graphical user interface 115 and then passed on to the next elements of the system 100. The domain ontology is distilled by the “distiller” component 120 into a “knowledge graph” 130 that is able to store the possible elements of the SoS (“structures” 132), their characteristics (“attributes” 133) and the potentials that the combination of some attributes brings (“capabilities” 131). The knowledge graph 130 can also store information on composition rules, including dynamic composition rules 126, structural composition rules 127, and behavioral composition rules 128. Note that some elements of system 100 in particular can be implemented in tasks scheduling physical components in a factory, medical planning in battle conditions, and resource planning for manufacturing components and other hardware components described herein.

The knowledge graph 130, together with the scenario information 110 from the analyst 105, feeds the “explorer” 135. The explorer 135 is a component of the system 100 that can generate design alternatives in a design space 145. Various technologies are possible for the implementation of the explorer 135, for example leading to a complete enumeration of the design alternatives 146 that satisfy the domain ontology and the scenario requirements, or leading to a subset of them, using an optional “synthesizer” component 140 that has the goal of filtering the design options while they are generated, before an actual evaluation occurs.

The design options can be translated by the “encoder” component 150 into models that a “solver” component 155 is able to evaluate against a set of key performance indicators (KPIs) that the user specified. The solver 155 encompasses multiple implementations. In certain embodiments, the possible SoS designs or design alternatives 146 can be evaluated by the solver 155 before the interactive solution exploration phase begins. In other embodiments, only selected SoS designs can be evaluated together with information on the neighborhood of such design options in the design space, and further design evaluations can be performed when triggered by the analysts 105.

The last components of the system 100 can be referred to as the “interactive solution exploration”. Once a set of solutions are computed, the “trade-off analyzer” component 160 can allow the user to visually explore them, can visualize the optimal solution for one or more KPIs, can identify the solution that provide the most robust option, can select portions of the SoS and trigger more detailed analysis and perturb the scenario to inspect the effect of a perturbation on a given solution. The “discoverer” component 165 has the goal of identifying and showing to the analysts 105 potential problems like bottlenecks or potential lack of resources. Also, multiple implementation options are possible for the discover component 165, ranging from brute force approaches that perturb a given design to identify potential issues, to more clever exploration of the design space and the constraints defined on it. The discoverer component 165 can also identify the causes for the issues through dependency analysis and can feed the information to the “insighter” component 170 that suggests to the user possible ways of making the design more resilient. All the components of the interactive solution exploration can be presented to the analyst 105 through a visualizer 175 in an interactive graphical user interface.

The first part of the system 100 builds on top of a functional modeling paradigm that represents an SoS modeling paradigm 125 in terms of attributes 133, structures 132 and capabilities 131 (capability-based model, CBM). The SoS modeling paradigm 125 can decouple the functions, referred to as capabilities 131 in this application, from the structures providing them. For example, avoiding explicit encoding of the fact that a surgical team is the structure 132 that can provide a treatment (capability 131) allows exploring a possibility of having a composition of other structures 132, each bringing an important characteristics (later called attributes 133), that together can perform the treatment.

Exploring other possibilities is achieved by creating a layer of abstraction, the attributes 133 (e.g., transportation skill), at the interface between the capabilities 131 (e.g., transportation) and the structures 131 that provide them (e.g., helicopters, ambulances). In this way, explorations on SoS architectures can exploit the flexibility given by not having encoded (hardcoded) the capability-structure mapping. Structures 132 can be dynamically mapped to capabilities if a disruption in the SoS occurs, or if a better performing option is identified to provide the same capability 131.

Behaviors are the way a capability 131 manifests itself. Behaviors are based on what attributes 133 are combined with the capability 131. Each behavior can be linked to a capability 131 in a many-to-one map. Many behaviors can be associated to a given capability 131 based on pre-conditions on the attributes of the capability providers (regardless of what is the actual structure holding them).

The generality of the approach is built on the fact that any problem scenario can be automatically represented and encoded once the appropriate elements have been distilled from the domain knowledge.

The SoS modeling paradigm layer 125 can enable dynamic composition 126 of SoS components. Composition rules are distilled from domain knowledge to form ontological rules for composing both structural and behavioral aspects of a system. These rules define such things as how attributes and behaviors are affected by the composition as well as what new attributes might be generated, enabling the operation of capabilities that were not supported by the single structures separately.

Both the CBM and dynamic composition 126 components can be encoded into the appropriate representation required by the solver 155 to perform enumeration and computation on the compositional design space. Together the CBM and dynamic composition 126 components can enable the automatic generation of SoS architectures, called SoS webs to highlight the presence of interrelationships between elements and domains in the system 100. The process of SoS webs generation is of generative design of composable SoS that can take care of transforming functional requirements and rules on the SoS element connections into a set of feasible SoS webs that can be further analyzed in terms of performance evaluation (with uncertainty when applicable) and dynamic composition exploration, to ensure computational tractability without losing power of discovery.

Key values of the capability-based model for composable SoS is enabling exploration of a large design trade-space without further human intervention; identification of unintuitive options that a human wouldn't have considered; discovery of desired and novel effects through functional (de)composition; and reasoning on different structural composition/fractionation options.

The basic constituents of the CBM are attributes 133, structures 132 and capabilities 131. An attribute 133 is a set of properties that define a characteristic of an entity in the system outside the context of a particular entity that may exhibit that attribute (e.g. health state, carrying capacity, surgical skills, etc.). A structure 132 is a physical entity that exposes attributes that provide a capability or set of capabilities (e.g. hospital, helicopter, surgical care team). A capability 131 is a function provided by a structure in the system that exhibits certain behavior based on certain criteria (e.g. treatment, transportation, etc.). A behavior is the manifestation of a capability when connected to certain attributes.

The CBM implements inheritance between structures 132. The CBM can constrain the possible connections between the capabilities 131 and the structures 132 of the system 100 through the interface provided by the attributes 133. For example, only structures 132 that provide surgical skills are allowed to perform treatment on structures 132 that demand a surgical skill. However, based on the properties of the surgical demand and of the surgical skills, a different behavior is exhibited by the treatment capability 131, resulting in a different surgical outcome. For example, an injury that requires surgery assisted by MRI has a low probability of success in a hospital without a MRI machine. The different behaviors associated to a capability 131 can be represented as alternative programming code blocks activated if the entry pre-condition(s) on the input attributes of that block is true. This allows dynamic activation of behaviors based on the current state of the system.

The distiller 120 represents the operation of distilling domain knowledge into the CBM formalism. To do so, the following steps are needed. (1) Declaration of system elemental components. This step includes manual generation of structures library following the defined formalism based on domain knowledge and initialization of properties based on specific instances of the structures, existing in the current state of the domain. (2) Definition of capabilities and their behaviors. This step can include enumeration of structure-specific capabilities exhibited by all considered structures in the domain, abstraction of structure-specific capabilities to structure-independent capabilities, through the use of the attributes layer, and definition of multiple behaviors for each capability, based on pre-conditions. (3) Definition of composition rules and composition structure specifications for the elements of the domain libraries.

The user input for the system can consist of a domain ontology and of a scenario definition, containing the available structure instances in the SoS and requirements in terms of the type of exploration is requested and the relevant metrics. The input is collected through the graphical user interface that, for example, allows the user to easily drag structures from the domain library onto the scenario definition, creating structure instances and editing their properties.

All this pieces of information are then translated into a domain specific markup language to be transmitted to the other components of the system.

Illustrated in FIG. 1C are a schematic representation of the process of applying examples of the solver 155. The solver 155 can perform an evaluation 159 whether a design alternative 146 or a portion of a design alternative 146 is acceptable 156, not acceptable 157, or undetermined 158. FIG. 1D illustrates an example of the trade-off analyzer 160 providing greater details for a portion 161 of the SoS system. FIG. 1E illustrates a discover component 165 identifying a potential issue 166 of the SoS system. Note that the solver 155, the trade-off analyzer 160 and the discover component of system 100 in particular can be implemented in tasks scheduling physical components in a factory, medical planning in battle conditions, and resource planning for manufacturing components and other hardware components described herein.

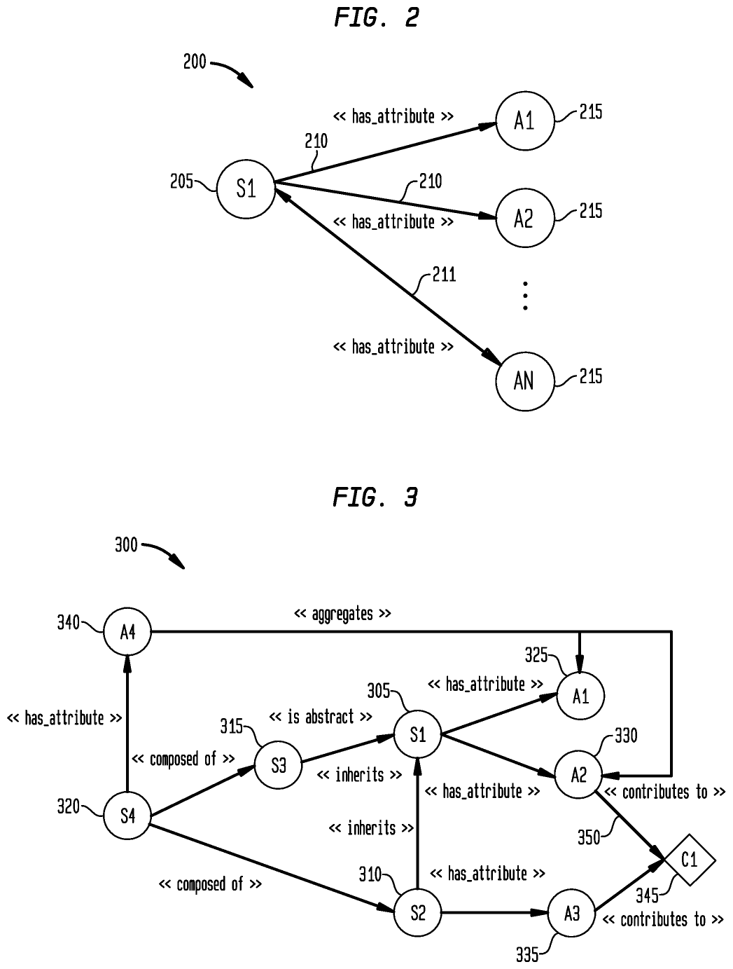

FIG. 2 illustrates an example of a type graph 200 inheritance 205, composition 210, and capabilities 215 in accordance with disclosed embodiments. The embodiment of the type graph 200 illustrated in FIG. 2 is for illustration only. FIG. 2 does not limit the scope of this disclosure to any particular implementation of a type graph.

The domain ontology has the goal to capture the domain knowledge of the SoS within which the problem scope lies. The domain ontology consists of triples in the form of node-edge-node. Nodes 205, 215 in the ontology represent entities of different categories, including structures 132, attributes 133 and capabilities 131. Edges in the ontology are directed edges and represent relationships 210 between two nodes 205, 215. Bi-directional relationships 210 are represented by bi-directional edges 211 (e.g. “is equivalent to”). Example of relationships 210 include, but are not limited to, has_name, has_attribute, has_value, is_a, contributes_to, is_composed_of, etc.

Structures 132 provide the fundamental unit of representation of domain knowledge for the SoS. A structure 132 S is a named aggregation of a set of properties called “attributes” 133 {A₁, A₂, . . . , A_{N}} that together represent the configuration of an entity in the SoS.

Structures 132 and their attributes 133 form one part of the SoS Ontology, referred as type graph 200, a formal structure that represents the problem formulation. The type graph 200 is a set of {V, E} where V={V₁, V₂, . . . , V_{N}} is a set of vertices or nodes 205, 215 in the graph representing a structure 132 or attribute 133 and E={E₁, E₂, . . . , E_{M}} is a set of edges between two nodes that define a semantic connection between them. In this case, a structure 132 S that has attributes 133 {A₁, A₂, . . . , A_{N}} would be semantically represented in the type graph according to the diagram in FIG. 2. Where the structure 132 is represented by node 205 and attributes 133 are represented by nodes 215.

Each structure type in SoS is represented as a distinct node in the type graph 200. A structure 132 can be fulfilled by a single concrete structure or a combination of concrete structures. Structures 132 themselves can be composed into aggregations to define new structures 132, typically where the aggregate properties are some combination of the composed attributes 133.

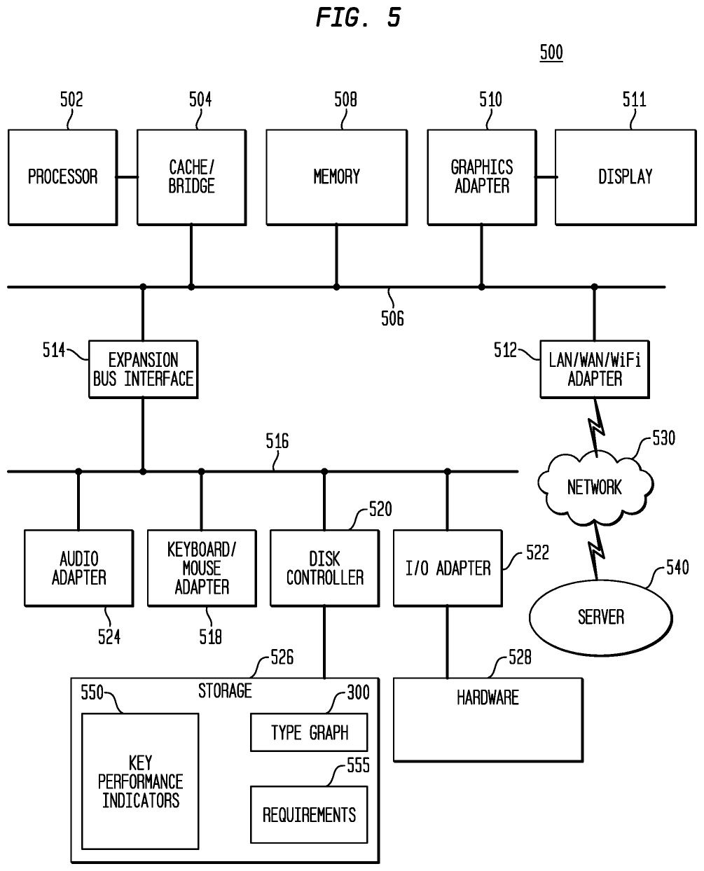

FIG. 3 illustrates an example of a type graph of an SoS 300 with inheritance 305, composition 310, and capabilities 315 in accordance with disclosed embodiments. The embodiment of the type graph of the SoS 300 illustrated in FIG. 3 is for illustration only. FIG. 3 does not limit the scope of this disclosure to any particular implementation of a type graph. The type graph 200 can be in the design space 145 shown in FIGS. 1A and 1B, and stored in the storage 526 shown in FIG. 5.

In the diagram in FIG. 3, S₁ 305 is a structure and S₄ 320 is a composition (with A₄ 340 as an aggregate property representing a composition of A₁ 325 and A₂ 330) of structures S₂ 310 and S₃ 315.

In addition to structures 132 and attributes 133, the type graph of the SoS 300 can also store capabilities 131. One or more attributes 133 can contribute to provide a capability 345, and this relationship 350 is named “contributes_to” in the type graph of the SoS 300. Depending on the solver 155 that is utilized in the system 100, capabilities 131 can be utilized directly, in conjunction with the knowledge of the instantiated structures in the SoS, to generate SoS designs, or can be processed and (automatically) translated into set of constraints by analyzing the pre- and post-conditions compatible with the instantiated structures in the system.

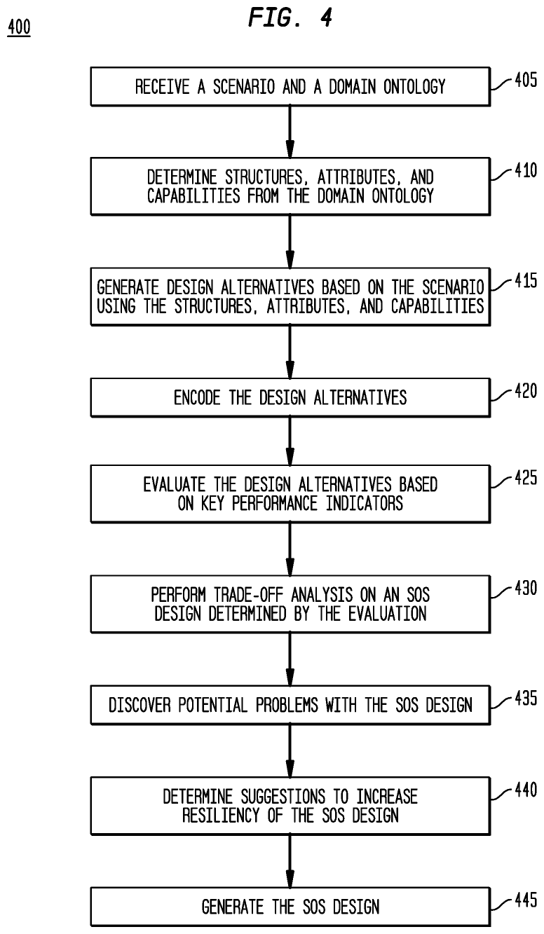

FIG. 4 illustrates a process 400 in accordance with disclosed embodiments, as can be performed by a control system, such as system 500 or the other elements described herein.

The process 400 provides operations that are used for complex system design generation, evaluation and exploration for virtually unlimited application. The process 400 provides encoding of a reusable domain-specific ontology that can be used to generate designs for different objectives and in different scenarios. The process 400 provide automatic generation of design options reducing human intervention and hence speeding up the process, using the explorer 135 and synthesizer 140 components. The process further provides the possibility to explore trade-offs and potential problems and suggest the user how to improve the design. The process also provides for domain ontology allowing composition of structures and capabilities to automatically explore non-trivial design options.

The system 500 receives a scenario and a domain ontology (405). The scenario 110 can be input by an analyst 105 and the domain ontology 111 can be input by a domain expert 106 in a user interface. The domain ontology 111 can include domain specific elements and rules. The scenario 110 can define instances available in the SoS and the objectives or key performance indicators.

The system 500 can determine structures, attributes, and capabilities from the domain ontology (410). The distiller 120 can extract the structures 132, attributes 133, and capabilities 131 into a knowledge graph, which stores these elements. The structure 132 is a physical entity that exposes attributes that provide a capability or set of capabilities. Examples of structures 132 can include, but are not limited to, a hospital, helicopter, surgical care team, etc. An attribute 133 is a set of properties that define a characteristic of an entity in the system outside the context of a particular entity that may exhibit that attribute. Examples of attributes 133 can include, but are not limited to a health state, a carrying capacity, surgical skills, etc. A capability 131 is a function provided by a structure in the system that exhibits certain behavior based on a certain criteria. Examples of capabilities can include, but are not limited to, treatment, transportation, etc.

The system 500 can generate design alternatives based on the scenario using the structures, attributes, and capabilities (415). The explorer 135 can generate design alternatives 146 in the design space 145. The design alternatives 146 are combinations of structures 132, capabilities 131, and attributes 133 connected by relationships 211. The relationship 211 can be unilateral or bi-directional. Examples of relationships 211 include, but are not limited to composed of, has attribute, contributes to, inherits, etc.

In certain embodiments, a synthesizer 140 can review the design alternatives that satisfy the domain ontology and scenario requirements. The synthesizer can reduce the alternative designs to a subset of alternative designs. The subset is a filtered amount of the alternative designs before the evaluation by the solver 155.

The system 500 can encode the design alternatives (420). The encoder 150 can translate the design alternatives 146 into a form readable by the solver 155.

The system 500 evaluates the design alternatives 146 based on key performance indicators (425). The key performance indicator is a performance measurement regarding the success of a node in the SoS system or the alternative designs or a relationship between nodes. The solver 155 can evaluate the design alternatives 146 in a manner that they can be utilized in the interactive solution exploration phase, which includes operations 425-440. In certain embodiments, an SoS design can be selected as a recommendation or standard form.

The system 500 can perform a trade-off analysis on an SoS design determined by the evaluation (430). The trade-off analyzer 160 can present the recommended or standard form of the SoS design. The trade-off analyzer 160 can allow the user to visualize the optimal solution for one or more KPIs, can identify a solution that provides the most robust option, can select portion of the SoS design and trigger a more detailed analysis on the portion of the SoS design and perturb the scenario to inspect the effect of a perturbation on a given solution.

The system 500 can discover potential problems with the SoS design (435). The discoverer component 165 can identify potential problems and display the potential problems to the user. Example of potential problems can include, but are not limited to, bottlenecks or potential lack of resources. Bottlenecks in production are areas were systems are not being utilized due to waiting on a previous system to complete a process. Potential lack of resources effects the systems by not being able to produce final products or processes requiring the lacked resources, possibly further affecting other systems that require the final product or processes.

The system 500 can determine suggestions to increase the resiliency of the SoS design (440). The insighter can analyze different nodes and relationship to determine whether additional structural elements can increase the resiliency of the product or process.

The system 500 can generate the SoS design (445). The system 500 can automatically generate an SoS design based on the solver 155. The system 500 can create revisions to the generated SoS design based on the interactive solution exploration phase. The generated SoS design can be displayed to a user for further interaction through the interface. The generated SoS design can be implemented in an industrial process and control system The generated SoS design can be packaged and transmitted to an external user.

FIG. 5 illustrates a block diagram of a data processing system in which an embodiment can be implemented, for example as a control system or other system to control processes as described herein, particularly configured by software or otherwise to perform the processes as described herein, and in particular as each one of a plurality of interconnected and communicating systems as described herein. The data processing system depicted includes a processor 502 connected to a level two cache/bridge 504, which is connected in turn to a local system bus 506. Local system bus 506 may be, for example, a peripheral component interconnect (PCI) architecture bus. Also connected to local system bus in the depicted example are a main memory 508 and a graphics adapter 510. The graphics adapter 510 may be connected to display 511.

Other peripherals, such as local area network (LAN)/Wide Area Network/Wireless (e.g. WiFi) adapter 512, may also be connected to local system bus 506. Expansion bus interface 514 connects local system bus 506 to input/output (I/O) bus 516. I/O bus 516 is connected to keyboard/mouse adapter 518, disk controller 520, and I/O adapter 522. Disk controller 520 can be connected to a storage 526, which can be any suitable machine usable or machine readable storage medium, including but not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices. Storage 526 can store, in particular, key performance indicators 550, or other data, programs, or instructions as described herein.

Also connected to I/O bus 516 in the example shown is audio adapter 524, to which speakers (not shown) may be connected for playing sounds. Keyboard/mouse adapter 518 provides a connection for a pointing device (not shown), such as a mouse, trackball, trackpointer, touchscreen, etc. I/O adapter 522 can be connected to communicate with or control hardware 528, which can include any hardware or physical components needed to perform processes described herein.

Those of ordinary skill in the art will appreciate that the hardware depicted in FIG. 5 may vary for particular implementations. For example, other peripheral devices, such as an optical disk drive and the like, also may be used in addition or in place of the hardware depicted. The depicted example is provided for the purpose of explanation only and is not meant to imply architectural limitations with respect to the present disclosure.

A data processing system in accordance with an embodiment of the present disclosure includes an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 512 can be connected to a network 530 (not a part of data processing system 500), which can be any public or private data processing system network or combination of networks, as known to those of skill in the art, including the Internet. Data processing system 500 can communicate over network 530 with server system 540, which is also not part of data processing system 500, but can be implemented, for example, as a separate data processing system 500.

Of course, those of skill in the art will recognize that, unless specifically indicated or required by the sequence of operations, certain steps in the processes described above may be omitted, performed concurrently or sequentially, or performed in a different order.

Those skilled in the art will recognize that, for simplicity and clarity, the full structure and operation of all data processing systems suitable for use with the present disclosure is not being depicted or described herein. Instead, only so much of a data processing system as is unique to the present disclosure or necessary for an understanding of the present disclosure is depicted and described. The remainder of the construction and operation of data processing system 500 may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims. Moreover, none of these claims are intended to invoke 35 USC § 112(f) unless the exact words “means for” are followed by a participle. The use of terms such as (but not limited to) “mechanism,” “module,” “device,” “unit,” “component,” “element,” “member,” “apparatus,” “machine,” “system,” “processor,” or “controller,” within a claim is understood and intended to refer to structures known to those skilled in the relevant art, as further modified or enhanced by the features of the claims themselves, and is not intended to invoke 35 U.S.C. § 112(f).

What is claimed is:

1. A process (400) performed by a control system (500), comprising:
receiving (405) a scenario (110) and a domain ontology (111);
determining (410) structures (132), attributes (133), and capabilities (131) from the domain ontology;
generating (415) design alternatives (146) based on the scenario using the structures, attributes, and capabilities;
performing (430) an evaluation (159) of the design alternatives based on the scenario;
generating (445) an SoS design (300) based on the evaluation; and
displaying the SoS design to a user.

2. The process of claim 1, further comprising:
identifying a portion (161) of the SoS design; and
triggering a detailed analysis (162) on the portion of the SoS design.

3. The process of claim 1, further comprising:
identifying potential problems (166); and
displaying the potential problems to the user.

4. The process of claim 3, wherein the potential problems include bottlenecking of the control system and potential lack of resources.

5. The process of claim 3, further comprising displaying suggestions (171) for altering the SoS design to increase resiliency.

6. The process of claim 1, further comprising filtering the design alternatives based on requirements (555) of the scenario before the evaluation occurs.

7. The process of claim 1, wherein the design alternatives are evaluated based on a key performance indicator (550) provided in the scenario.

8. A control system (500) comprising:
a memory (508); and
a processor (502) in communication with the memory, wherein processor is configured to:
receive (405) a scenario (110) and a domain ontology (111);
determine (410) structures (132), attributes (133), and capabilities (131) from the domain ontology;
generate (415) design alternatives (146) based on the scenario using the structures, attributes, and capabilities;
perform (430) an evaluation (159) of the design alternatives based on the scenario;
generate (445) an SoS design (300) based on the evaluation; and
display the SoS design to a user.

9. The control system of claim 8, wherein the processor is further configured to:
identify a portion (161) of the SoS design; and
trigger a detailed analysis (162) on the portion of the SoS design.

10. The control system of claim 8, wherein the processor is further configured to:
identify potential problems (166); and
display the potential problems to a user.

11. The control system of claim 10, wherein the potential problems include bottlenecking of the control system and potential lack of resources.

12. The control system of claim 10, wherein the processor is further configured to display suggestions (171) for altering the SoS design to increase resiliency.

13. The control system of claim 8, wherein the processor is further configured to filter the design alternatives based on requirements (555) of the scenario before the evaluation occurs.

14. The control system of claim 8, wherein the design alternatives are evaluated based on a key performance indicator (550) provided in the scenario.

15. A non-transitory computer-readable medium (508) storing executable instructions that, when executed, cause a processor (502) to:
receive (405) a scenario (110) and a domain ontology (111);
determine (410) structures (132), attributes (133), and capabilities (131) from the domain ontology;
generate (415) design alternatives (146) based on the scenario using the structures, attributes, and capabilities;
perform (430) an evaluation (159) of the design alternatives based on the scenario;
generate (445) an SoS design (300) based on the evaluation; and
display the SoS design to a user.

16. The non-transitory computer-readable medium of claim 15, wherein the executable instructions further cause processor to:
identify a portion (161) of the SoS design; and
trigger a detailed analysis (162) on the portion of the SoS design.

17. The non-transitory computer-readable medium of claim 15, wherein the executable instructions further cause processor to:
identify potential problems (166); and
display the potential problems to a user.

18. The non-transitory computer-readable medium of claim 17, wherein the potential problems include bottlenecking of the system and potential lack of resources.

19. The non-transitory computer-readable medium of claim 17, wherein the executable instructions further cause processor to display suggestions (171) for altering the SoS design to increase resiliency.

20. The non-transitory computer-readable medium of claim 15, wherein the executable instructions further cause processor to filter design alternatives based on requirements (555) of the scenario before the evaluation occurs.
